(19) United States
(12) Patent Application Publication
(10) Pub. No.: US 2022/0231174 A1
(43) Pub. Date: Jul. 21, 2022

(54) SEMICONDUCTOR ELEMENT AND SEMICONDUCTOR DEVICE

(71) Applicant: FLOSFIA INC., Kyoto (JP)

(72) Inventor: Osamu IMAFUJI, Kyoto (JP)

(21) Appl. No.: 17/711,342

(22) Filed: Apr. 1, 2022

Related U.S. Application Data
(63) Continuation-in-part of application No. PCT/JP2020/037521, filed on Oct. 2, 2020.

(30) Foreign Application Priority Data
Oct. 3, 2019 (JP) 2019-182969

(51) Int. Cl. H01L 29/872; H01L 29/66; H01L 29/47

(52) U.S. Cl. CPC H01L 29/872; H01L 29/24; H01L 29/47; H01L 29/66969

(57) ABSTRACT

Provided is a semiconductor element including at least a multilayer structure including a semiconductor layer, a first metal layer, a second metal layer and a third metal layer, the semiconductor layer including an oxide semiconductor film, the first metal layer, the second metal layer and the third metal layer being arranged on the semiconductor layer, the first metal layer, the second metal layer and the third metal layer respectively including one or two or more different metals, the first metal layer being in ohmic contact with the semiconductor layer, the second metal layer being disposed between the first metal layer and the third metal layer, and the second metal layer containing Pt or/and Pd.

### CROSS REFERENCE TO RELATED APPLICATION

This application is a continuation-in-part application of International Patent Application No. PCT/JP2020/037521 (Filed on Oct. 2, 2020), which claims the benefit of priority from Japanese Patent Application No. 2019-182969 (filed on Oct. 3, 2019).

The entire contents of the above applications, which the present application is based on, are incorporated herein by reference.

### FIELD OF INVENTION

The present disclosure relates to a semiconductor element that is useful as, e.g., a power device, and a semiconductor device and a semiconductor system using the semiconductor element.

### DESCRIPTION OF THE RELATED ART

Gallium oxide (Ga₂O₃) is a transparent semiconductor that has a wide bandgap of 4.8-5.3 eV at room temperature and that absorbs little visible and ultraviolet light. Therefore, in particular, gallium oxide is a promising material for use in optical/electronic devices that operate in a deep ultraviolet range and transparent electronics, and in recent years, development of photodetectors, light-emitting diodes (LED) and transistors based on gallium oxide (Ga₂O₃) has been underway.

There are five, α, β, γ, σ and ε, crystal structures of gallium oxide (Ga₂O₃), and generally, the most stable structure is β-Ga₂O₃. However, β-Ga₂O₃ has a β-gallia structure, and unlike crystalline systems and the like generally used in electronic materials, is not necessarily suitable for use in semiconductor elements. Also, growth of a β-Ga₂O₃ thin film needs a high substrate temperature and a high degree of vacuum, causing a problem of an increase in manufacturing cost. In addition, in the case of β-Ga₂O₃, even a high concentration (for example, no less than 1×10¹⁹/cm³) of a dopant (Si) needs to be subjected to annealing treatment at a high temperature of 800° C. to 1100° C. after ion implantation, to use the dopant as a doner.

On the other hand, α-Ga₂O₃ has a crystal structure that is the same as that of a sapphire substrate, which has already been widely used, and thus, is suitable for use in optical and electronic devices. Furthermore, α-Ga₂O₃ has a bandgap that is wider than that of β-Ga₂O₃, and thus, is particularly useful for power devices. Therefore, semiconductor elements using α-Ga₂O₃ as a semiconductor have been anticipated.

Semiconductor elements using β-Ga₂O₃ as a semiconductor and using two layers of a Ti layer and an Au layer, three layers of a Ti layer, an Al layer and an Au layer or four layers of a Ti layer, an Al layer, an Ni layer and an Au layer as an electrode providing ohmic characteristics meeting the semiconductor have been known.

Also, semiconductor elements using β-Ga₂O₃ as a semiconductor and using any of Au, Pt and a stack of Ni and Au as an electrode providing Schottky characteristics meeting the semiconductor have been known.

However, if any of the above-described electrodes is applied to a semiconductor element using α-Ga₂O₃ as a semiconductor, there are problems such as failure of the electrode to function as a Schottky electrode or an ohmic electrode, failure of the electrode to be bonded to a film and impairment of semiconductor characteristics. Furthermore, the above-described electrode configurations each have provided no practically satisfactory semiconductor element because of, e.g., occurrence of leak current from an electrode end portion.

### SUMMARY OF THE INVENTION

According to an example of the present disclosure, there is provided a semiconductor element including; at least a multilayer structure including a semiconductor layer, a first metal layer, a second metal layer and a third metal layer, the semiconductor layer including an oxide semiconductor film, the first metal layer, the second metal layer and the third metal layer being arranged on the semiconductor layer, the first metal layer, the second metal layer and the third metal layer respectively including one or two or more different metals, the first metal layer being in ohmic contact with the semiconductor layer, the second metal layer being disposed between the first metal layer and the third metal layer, and the second metal layer containing Pt or/and Pd.

Thus, in a semiconductor element of the present disclosure, the semiconductor element of the present disclosure curbs diffusion of, e.g., oxygen into an ohmic electrode by an oxide semiconductor and provides a favorable ohmic characteristic.

### BRIEF DESCRIPTION OF THE DRAWINGS

FIG. 1 is a sectional view schematically illustrating a preferable mode of a semiconductor element of the present disclosure;

FIG. 2 is a diagram illustrating a mode of a preferable method of manufacturing the semiconductor element in FIG. 1;

FIG. 3 is a diagram illustrating a mode of a preferable method of manufacturing the semiconductor element in FIG. 1;

FIG. 4 is a diagram illustrating a mode of a preferable method of manufacturing the semiconductor element in FIG. 1;

FIG. 5 is a diagram illustrating a mode of a preferable method of manufacturing the semiconductor element in FIG. 1;

FIG. 6 is a sectional view schematically illustrating a preferable mode of the semiconductor element of the present disclosure;

FIG. 7 is a diagram illustrating a result of SEM-EDS where Ti/Ni/Au was used as an ohmic electrode;

FIG. 8 is a diagram schematically illustrating a preferable example of a power supply system;

FIG. 9 is a diagram schematically illustrating a preferable example of a system device;

FIG. 10 is a diagram schematically illustrating a preferable example of a power supply circuit diagram of a power supply device;

FIG. 11 is a diagram schematically illustrating a preferable example of a semiconductor device;

FIG. 12 is a diagram schematically illustrating a preferable example of a power card;

FIG. 13 includes diagrams each illustrating a porosity of a porous layer: FIG. 13(a) illustrates a porosity of a porous layer after bonding with normal annealing; and FIG. 13(b) illustrates a porosity where thermal compression bonding was further performed for one hour after annealing;

FIG. 14 includes photographs illustrating a partial outer appearance of an ohmic electrode after sintering in a test example: FIG. 14(a) is a photograph illustrating an outer appearance after sintering where Ti/Pt/Au was used as an ohmic electrode; and FIG. 14(b) is a photograph illustrating an outer appearance after sintering where Ti/Ni/Au was used as an ohmic electrode;

FIG. 15 includes graphs illustrating temperature (sintering temperature) dependance of a contact resistivity in a case where Ti/Pt/Au was used as an ohmic electrode and that in a case where Ti/Ni/Au was used as an ohmic electrode, respectively, in a test example;

FIG. 16 is a diagram schematically illustrating a multilayer structure that is a major portion of the semiconductor element of the present disclosure; and

FIG. 17 is a sectional view schematically illustrating a product of an embodiment of the semiconductor element of the present disclosure.

### DETAILED DESCRIPTION

The inventors of present disclosure found out that Ti may diffuse if ohmic electrode containing Ti/Au. The inventors of present disclosure found out that oxygen in an oxide semiconductor may diffuse in ohmic electrode if a Ti anti-diffusion film is provided between a Ti layer and a Au layer.

According to an example of the present disclosure, there is provided a semiconductor element including, at least a multilayer structure including a semiconductor layer, a first metal layer, a second metal layer and a third metal layer, the semiconductor layer including an oxide semiconductor film, the first metal layer, the second metal layer and the third metal layer being arranged on the semiconductor layer, the first metal layer, the second metal layer and the third metal layer respectively including one or two or more different metals, the first metal layer being in ohmic contact with the semiconductor layer, the second metal layer being disposed between the first metal layer and the third metal layer, and the second metal layer containing Pt or/and Pd.

Thus, in a semiconductor element of the present disclosure, the semiconductor element of the present disclosure curbs diffusion of, e.g., oxygen into an ohmic electrode by an oxide semiconductor and provides a favorable ohmic characteristic.

Embodiments of the present disclosure will be described below with reference to the accompanying drawings. In the following description, the same parts and components are designated by the same reference numerals. The present embodiment includes, for example, the following disclosures.

### [Structure 1]

A semiconductor element including; at least a multilayer structure including a semiconductor layer, a first metal layer, a second metal layer and a third metal layer, the semiconductor layer including an oxide semiconductor film, the first metal layer, the second metal layer and the third metal layer being arranged on the semiconductor layer, the first metal layer, the second metal layer and the third metal layer respectively including one or two or more different metals, the first metal layer being in ohmic contact with the semiconductor layer, the second metal layer being disposed between the first metal layer and the third metal layer, and the second metal layer containing Pt or/and Pd.

### [Structure 2]

The semiconductor element according to [Structure 1], wherein the oxide semiconductor film has a corundum structure.

### [Structure 3]

The semiconductor element according to [Structure 2], wherein a principal plane of the oxide semiconductor film is an m-plane.

### [Structure 4]

The semiconductor element according to any of [Structure 1] to [Structure 3], wherein the oxide semiconductor film contains gallium oxide and/or iridium oxide.

### [Structure 5]

The semiconductor element according to any of [Structure 1] to [Structure 4], wherein the oxide semiconductor film contains gallium oxide.

### [Structure 6]

The semiconductor element according to any of [Structure 1] to [Structure 5], wherein the oxide semiconductor film contains a dopant.

### [Structure 7]

The semiconductor element according to any of [Structure 1] to [Structure 6], wherein the first metal layer is a Ti layer or an In layer.

### [Structure 8]

The semiconductor element according to any of [Structure 1] to [Structure 7], wherein the third metal layer is a metal layer including at least one or two or more metals selected from Au, Ag and Cu.

### [Structure 9]

The semiconductor element according to any of [Structure 1] to [Structure 8], wherein a porous layer is further disposed in contact with the third metal layer.

### [Structure 10]

The semiconductor element according to [Structure 9], wherein a porosity of the porous layer is no more than 10%.

### [Structure 11]

The semiconductor element according to [Structure 9] or [Structure 10], wherein the porous layer contains a precious metal.

### [Structure 12]

The semiconductor element according to any of [Structure 9] to [Structure 11], wherein a substrate is further disposed on the porous layer.

### [Structure 13]

The semiconductor element according to any of [Structure 1] to [Structure 12], further comprising a Schottky electrode.

### [Structure 14]

The semiconductor element according to [Structure 13], wherein the Schottky electrode contains Mo and/or Co.

### [Structure 15]

The semiconductor element according to [Structure 13] or [Structure 14], wherein the Schottky electrode is disposed on a first surface side of the oxide semiconductor film and an ohmic electrode is disposed on a second surface side of the oxide semiconductor film, and wherein the second surface side is opposite from the first surface side.

### [Structure 16]

The semiconductor element according to any of [Structure 13] to [Structure 15], wherein the Schottky electrode includes at least a first metal layer, a second metal layer and a third metal layer, the first metal layer of the Schottky electrode, the second metal layer of the Schottky electrode and the third metal layer of the Schottky electrode respectively include different metals, the second metal layer of the Schottky electrode is disposed between the first metal layer of the Schottky electrode and the third metal layer of the Schottky electrode, and the first metal layer of the Schottky electrode is disposed on the semiconductor layer side relative to the third metal layer of the Schottky electrode.

### [Structure 17]

The semiconductor element according to [Structure 16], wherein the first metal layer of the Schottky electrode is a Co layer or an Mo layer.

### [Structure 18]

The semiconductor element according to [Structure 16] or [Structure 17], wherein the second metal layer of the Schottky electrode is a Ti layer.

### [Structure 19]

The semiconductor element according to any of [Structure 16] to [Structure 18], wherein the third metal layer of the Schottky electrode is an Al layer.

### [Structure 20]

A semiconductor element including; at least a semiconductor layer including an oxide semiconductor film, a Schottky electrode, and an ohmic electrode, the Schottky electrode including a Co layer or an Mo layer, and the ohmic electrode including at least a first metal layer, a second metal layer and a third metal layer, the first metal layer being a Ti layer or an In layer, the second metal layer being a Pt layer or a Pd layer, and the third metal layer being a metal layer including at least one or two or more metals selected from Au, Ag and Cu.

### [Structure 21]

The semiconductor element according to any of [Structure 1] to [Structure 20], wherein the semiconductor layer is an n-type oxide semiconductor layer.

### [Structure 22]

The semiconductor element according to any of [Structure 1] to [Structure 21], wherein the semiconductor element is a vertical device.

### [Structure 23]

The semiconductor element according to any of [Structure 1] to [Structure 22], wherein the semiconductor element is a power device.

### [Structure 24]

A semiconductor device including at least a semiconductor element bonded to a lead frame, a circuit substrate or a heat dissipation substrate with a bonding member, wherein the semiconductor element is the semiconductor element according to any of [Structure 1] to [Structure 23].

### [Structure 25]

The semiconductor device according to [Structure 24], wherein the semiconductor device is a power module, an inverter or a converter.

### [Structure 26]

The semiconductor device according to [Structure 24] or [Structure 25], wherein the semiconductor device is a power card.

### [Structure 27]

A semiconductor system including a semiconductor element or a semiconductor device, wherein the semiconductor element is the semiconductor element according to claim 1 and the semiconductor device is the semiconductor device according to any of [Structure 24] to [Structure 26].

The semiconductor element of the present disclosure is a semiconductor element including at least a multilayer structure including a semiconductor layer, a first metal layer, a second metal layer and a third metal layer, the semiconductor layer including an oxide semiconductor film, the first metal layer, the second metal layer and the third metal layer being arranged on the semiconductor layer, the first metal layer, the second metal layer and the third metal layer including respective one or two more different metals, the first metal layer being in ohmic contact with the semiconductor layer, the second metal layer being disposed between the first metal layer and the third metal layer, and the second metal layer containing Pt or/and Pd. The multilayer structure is not specifically limited as long as, for example, as illustrated in FIG. 16, a first metal layer 102a, a second metal layer 102b and a third metal layer 102c are arranged on a semiconductor layer 101 including an oxide semiconductor film.

The oxide semiconductor film (hereinafter, also simply referred to as a “semiconductor layer” or a “semiconductor film”) is not specifically limited as long as the oxide semiconductor film is a semiconductor film containing an oxide; however, in the present disclosure, the oxide semiconductor film is preferably a semiconductor film containing a metal oxide, more preferably a semiconductor film containing a crystalline oxide semiconductor, and most preferably a semiconductor film containing a crystalline oxide semiconductor as a major component. Also, in the present disclosure, the crystalline oxide semiconductor contains preferably one or two or more metals selected from group 9 (for example, cobalt, rhodium or iridium) and group 13 (for example, aluminum, gallium or indium) of the periodic table, more preferably at least one metal selected from aluminum, indium, gallium and iridium, and most preferably at least gallium or iridium. A crystal structure of the crystalline oxide semiconductor is not specifically limited. Examples of the crystal structure of the crystalline oxide semiconductor include, e.g., a corundum structure, a β-gallia structure and a hexagonal crystal structure (for example, an ε-structure). In the present disclosure, it is preferable that the crystalline oxide semiconductor have a corundum structure and it is more preferable that the crystalline oxide semiconductor have a corundum structure and a principal plane is an m-plane because such crystalline oxide semiconductor is capable of curbing diffusion of, e.g., oxygen and have more excellent electrical characteristics. Also, the crystalline oxide semiconductor may have an off angle. In the present disclosure, the semiconductor film preferably contains gallium oxide and/or iridium oxide and more preferably contains α-Ga₂O₃ and/or α-Ir₂O₃. Here, the “major component” means that the crystalline oxide semiconductor is contained at an atom ratio of preferably no less than 50%, more preferably no less than 70%, still more preferably no less than 90% to all components of the semiconductor layer and means that the atom ratio may be 100%. Also, a thickness of the semiconductor layer is not specifically limited and may be no more than 1 μm or may be no less than 1 μm; however, in the present disclosure, the thickness of the semiconductor layer is preferably no less than 1 μm, and more preferably no less than 10 μm. A surface area of the semiconductor film is not specifically limited and may be no less than 1 mm² or may be no more than 1 mm², but is preferably 10 mm² to 300 cm², and more preferably 100 mm² to 100 cm². Also, the semiconductor film is preferably a single crystal film but may be a polycrystalline film or a crystal film containing a polycrystal. Also, the oxide semiconductor film is a semiconductor layer of a multi-layer film containing at least a first oxide semiconductor film and a second oxide semiconductor film, and where a Schottky electrode is provided on the first oxide semiconductor film, it is preferable that the multi-layer film is a multi-layer film in which a carrier density of the first oxide semiconductor film is smaller than a carrier density of the second oxide semiconductor film. In this case, at least the second oxide semiconductor film normally contains a dopant and it is possible to arbitrarily set a carrier density of the semiconductor layer by adjusting a doping amount.

The semiconductor layer preferably contains a dopant. The dopant is not specifically limited and may be a publicly known one. Example of the dopant include, e.g., n-type dopants such as tin, germanium, silicon, titanium, zirconium, vanadium and niobium and p-type dopants such as magnesium, calcium and zinc. In the present disclosure, the semiconductor layer preferably contains an n-type dopant and is more preferably an n-type oxide semiconductor layer. Also, in the present disclosure, it is preferable that the n-type dopant be Sn, Ge or Si. An amount of the dopant contained is preferably no less than 0.00001 atom %, more preferably 0.00001 atom % to 20 atom %, and most preferably 0.00001 atom % to 10 atom % in a composition of the semiconductor layer. More specifically, a concentration of the dopant may normally approximately 1×10¹⁶/cm³ to 1×10²²/cm³ or the concentration of the dopant may be set to be a low concentration of, for example, approximately no more than 1×10¹⁷/cm³. Also, according to an aspect of the present disclosure, the dopant may be contained in a high concentration of approximately 1×10²⁰/cm³. Also, a concentration of fixed charge in the semiconductor layer is not specifically limited; however, in the present disclosure, it is preferable that the concentration of fixed charge in the semiconductor layer be no more than 1×10¹⁷/cm³ because such concentration enables more favorably forming a depletion layer with the semiconductor layer.

The semiconductor layer may be formed using a publicly known method. Examples of a method of forming the semiconductor layer include, e.g., a CVD method, an MOCVD method, an MOVPE method, a mist CVD method, a mist epitaxy method, an MBE method, an HVPE method, a pulse growth method and an ALD method. In the present disclosure, it is preferable that the method of forming the semiconductor layer be the mist CVD method or the mist epitaxy method. In the mist CVD method or the mist epitaxy method, the semiconductor layer is formed by, for example, atomizing a raw material solution (atomization step) to make droplets be suspended, and after the atomization, carrying the resulting atomized droplets above a base with a carrier gas (carrying step), and subsequently stacking a semiconductor film containing a crystalline oxide semiconductor as a major component on the base through thermal reaction of the atomized droplets in the vicinity of the base (film forming step).

### (Atomization Step)

In the atomization step, the raw material solution is atomized. A method of atomization of the raw material solution is not specifically limited as long as such method enables atomization of the raw material solution and may be a publicly known method; however, in the present disclosure, an atomization method using ultrasound is preferable. Atomized droplets obtained using ultrasound are preferable because of having an initial velocity of zero and being suspended in air. The atomized droplets (including mist) are very preferable because the atomized droplets are not, for example, those sprayed with a sprayer but are suspended in space and are carried as gas, and thus, are not damaged by collision energy. A size of each of the droplets is not specifically limited and may be around several millimeters, but preferably no more than 50 μm, more preferably 100 nm to 10 μm.

### (Raw Material Solution)

The raw material solution is not specifically limited as long as atomization of the raw material solution is possible and the raw material solution contains a raw material that enables forming of a semiconductor film, and may be an inorganic material or may be an organic material. In the present disclosure, the raw material is preferably a metal or a metal compound, more preferably one or two or more metals selected from aluminum, gallium, indium, iron, chromium, vanadium, titanium, rhodium, nickel, cobalt and iridium.

In the present disclosure, as the raw material solution, one obtained by dissolving or dispersing the metals in an organic solvent or water in the form of a complex or a salt may be preferably used. Examples of the form of a complex include, e.g., acetylacetonate complexes, carbonyl complexes, ammine complexes and hydride complexes. Examples of the form of a salt include, e.g., organic metal salts (for example, metal acetates, metal oxalates, metal citrates, etc.), metal sulfide salts, metal nitrate salts, metal phosphate salts and metal halide salts (for example, metal chloride salts, metal bromide salts, metal iodide salts, etc.).

Also, it is preferable that additive agents such as a hydrohalic acid and an oxidizing agent be mixed in the raw material solution. Examples of the hydrohalic acid include, e.g., a hydrobromic acid, a hydrochloric acid and a hydroiodic acid, and among others, a hydrobromic acid or a hydroiodic acid is preferable because of being capable of more efficiently curbing generation of abnormal grains. Examples of the oxidizing agent include, e.g., peroxides such as hydrogen peroxide (H₂O₂), sodium peroxide (Na₂O₂), barium peroxide (BaO2) and benzoyl peroxide (C₆H₅CO)₂O₂ and organic peroxides such as a hypochlorous acid (HClO), a perchloric acid, a nitric acid, ozone water, acetyl hydroperoxide and nitrobenzene.

The raw material solution may contain a dopant. A dopant being contained in the raw material solution enables doping to be performed favorably. The dopant is not specifically limited as long as such dopant does not hinder the present disclosure. Examples of the dopant include, e.g., n-type dopants such as tin, germanium, silicon, titanium, zirconium, vanadium and niobium and p-type dopants such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Ti, Pb, N and P. An amount of the dopant contained is appropriately set using a calibration curve indicating a relationship of a concentration of a dopant in a raw material with a desired carrier density.

A solvent of the raw material solution is not specifically limited and may be an inorganic solvent such as water or may be an organic solvent such as alcohol or may be a mixed solvent of an inorganic solvent and an organic solvent. In the present disclosure, the solvent preferably contains water, and more preferably is a mixed solvent of water and alcohol.

### (Carrying Step)

In the carrying step, the atomized droplets are carried into a film forming chamber by the carrier gas. The carrier gas is not specifically limited as long as the carrier gas does not hinder the present disclosure, and preferable examples of the carrier gas include, e.g., inert gases such as oxygen, ozone, nitrogen and argon and reducing gases such as hydrogen gas and forming gas. Also, for a type of the carrier gas, a single type or two or more types of the carrier gas may be used, and, e.g., a dilute gas with a flow rate lowered (for example, a 10-fold diluted gas) may further be used as a second carrier gas. Also, the number of locations for supply of the carrier gas is not limited to one but may be two or more. A flow rate of the carrier gas is not specifically limited but is preferably 0.01 to 20 L/minute, and more preferably 1 to 10 L/minute. In the case of a dilute gas, a flow rate of the dilute gas is preferably 0.001 to 2 L/minute, and more preferably 0.1 to 1 L/minute.

### (Film Forming Step)

In the film forming step, the semiconductor film is formed on the base through thermal reaction of the atomized droplets in the vicinity of the base. It is only necessary that the atomized droplets react with heat, and conditions, etc., of the thermal reaction are not specifically limited as long as such conditions, etc., do not hinder the present disclosure. In the present step, the thermal reaction is normally performed at a temperature that is equal to or exceeds an evaporation temperature of the solvent but preferably no more than a temperature that is not too high (for example, 1000° C.), more preferably no more than 650° C., and most preferably no more than 300° C. to 650° C. Also, the thermal reaction may be performed under any atmosphere of vacuum, a non-oxygen atmosphere (for example, an inert gas atmosphere, etc.), a reducing gas atmosphere and an oxygen atmosphere as long as such atmosphere does not hinder the present disclosure; however, it is preferable that the thermal reaction be performed under an inert gas atmosphere or an oxygen atmosphere. Also, the thermal reaction may be performed under any condition of atmospheric pressure, increased pressure and reduced pressure; however, in the present disclosure, it is preferable that the thermal reaction be performed under atmospheric pressure. Note that it is possible to set a film thickness of the semiconductor film by adjusting film forming time.

### (Base)

The base is not specifically limited as long as the base is capable of supporting the semiconductor film. A material of the base is also not specifically limited as long as the material does not hinder the present disclosure, and may be a publicly known base, and may be an organic compound or may be an inorganic compound. A shape of the base may be any shape and the base is effective in any and all shapes including, for example, plate-like shapes such as a flat plate and a circular plate, a fibrous shape, a rod-like shapes, a columnar shape, a prism shape, a tubular shape, a helical shape, a spherical shape and a ring-like shape; however, in the present disclosure, a substrate is preferable. A thickness of the substrate is not specifically limited in the present disclosure.

The substrate is not specifically limited as long as the substrate has a plate-like shape and serves as a support for the semiconductor film. The substrate may be an insulator substrate, may be a semiconductor substrate or may be a metal substrate or an electrically conductive substrate; however, the substrate is preferably an insulator substrate and is also preferably a substrate including a metal film on a surface. Examples of the substrate include, e.g., a base substrate containing a substrate material having a corundum structure as a major component, a base substrate containing a substrate material having a β-gallia structure as a major component and a base substrate containing a substrate material having a hexagonal crystal structure as a major component. Here, the “major component” means that any of the substrate materials each having a particular crystal structure is contained at an atom ratio of preferably no less than 50%, more preferably no less than 70%, still more preferably no less than 90% to all components of the substrate material, and the atom ratio may be 100%.

The substrate material is not specifically limited as long as the substrate material does not hinder the present disclosure, and may be a publicly known one. Preferable examples of the substrate material having a corundum structure include α-Al₂O₃ (sapphire substrate) and α-Ga₂O₃, and more preferable examples of the same include, e.g., an a-plane sapphire substrate, an m-plane sapphire substrate, an r-plane sapphire substrate, a c-plane sapphire substrate and an α-gallium oxide substrate (a-plane, m-plane or r-plane). Examples of the base substrate containing a substrate material having a β-gallia structure as a major component include, e.g., a β-Ga₂O₃ substrate and a mixed crystal substrate containing Ga₂O3 and Al₂O₃ in which Al₂O₃ is contained at no less than 0 wt % and no more than 60 wt %. Also, examples of the base substrate containing a substrate material having a hexagonal crystal structure as a major component include, e.g., an SiC substrate, a ZnO substrate and a GaN substrate.

In the present disclosure, after the film forming step, annealing treatment may be performed. A temperature of the annealing treatment is not specifically limited as long as such temperature does not hinder the present disclosure, and is normally 300° C. to 650° C., and preferably 350° C. to 550° C. Also, a length of time of the annealing treatment is normally 1 minute to 48 hours, preferably 10 minutes to 24 hours, and more preferably 30 minutes to 12 hours. Note that the annealing treatment may be performed under any atmosphere as long as such atmosphere does not hinder the present disclosure. The atmosphere may be a non-oxygen atmosphere or an oxygen atmosphere. Examples of the non-oxygen atmosphere include, e.g., inert gas atmospheres (for example, a nitrogen atmosphere) and reducing gas atmospheres, and in the present disclosure, an inert gas atmosphere is preferable and a nitrogen atmosphere is more preferable.

Also, in the present disclosure, the semiconductor film may be provided directly on the base or the semiconductor film may be provided on the base with other layers in between such as a stress relaxation layer (for example, a buffer layer or an ELO layer) and a removal sacrificial layer. Methods for forming the respective layers are not specifically limited and may be publicly known methods, but in the present disclosure, a mist CVD method is preferable.

In the present disclosure, the semiconductor film may be used in a semiconductor element as the semiconductor layer after use of a publicly known method of, e.g., removal of the semiconductor film from, e.g., the base or may be used as it is in a semiconductor element as the semiconductor layer.

The first metal layer, the second metal layer and the third metal layer in the multilayer structure are not specifically limited as long as the first metal layer, the second metal layer and the third metal layer include respective one or two or more different metals, the second metal layer is disposed between the first metal layer and the third metal layer, the second metal layer contains Pt or/and Pd and the first metal layer is in ohmic contact with the semiconductor layer. Component metals of the respective metal layers of the multilayer structure are not specifically limited and examples of the component metals include, e.g., transition metals and base metals. In the present disclosure, it is preferable that the semiconductor element include at least the first metal layer, the second metal layer and the third metal layer as an ohmic electrode. Note that the ohmic electrode may include a multi-layered electrically conductive layer further including a fourth metal layer and a fifth metal layer as long as such multi-layered electrically conductive layer does not hinder the present disclosure, and may include, for example, 1 to 100 electrically conductive layers.

The ohmic electrode is not specifically limited as long as the ohmic electrode includes at least a first metal layer that is in ohmic contact with the semiconductor layer, a second metal layer and a third metal layer, the first metal layer, the second metal layer and the third metal layer include respective one or two or more different metals, the second metal layer is disposed between the first metal layer and the third metal layer and the second metal layer is a Pt layer or a Pd layer. In the present disclosure, it is preferable that the first metal layer of the ohmic electrode be a Ti layer or an In layer. Also, it is preferable that the third metal layer of the ohmic electrode be a metal layer including at least one or two or more metals selected from an Au layer, an Ag layer and a Cu layer. A thickness of each of the metal layers of the ohmic electrode is not specifically limited but is preferably 0.1 nm to 10 μm, and more preferably 1 nm to 1000 nm.

A method of forming the ohmic electrode is not specifically limited and may be a publicly known method. Specific examples of the method of forming the ohmic electrode include, e.g., a dry method and a wet method. Examples of the dry method include, e.g., sputtering, vacuum vapor deposition and CVD. Examples of the wet method include, e.g., screen printing and die coating.

Also, the semiconductor element may include a Schottky electrode or may include no Schottky electrode. In the present disclosure, as a preferable form, it is preferable that the semiconductor element be a Schottky barrier diode. The Schottky electrode (hereinafter, simply referred to as an “electrode layer”) is not specifically limited as long as the Schottky electrode has electrical conductivity and is usable as a Schottky electrode and does not hinder the present disclosure. A component material of the electrode layer may be an electrically conductive inorganic material or may be an electrically conductive organic material. In the present disclosure, it is preferable that the material of the electrode be a metal. Preferable examples of the metal include, e.g., at least one metal selected from groups 4 to 10 of the periodic table. Examples of a metal in group 4 of the periodic table include, e.g., titanium (Ti), zirconium (Zr) and hafnium (Hf). Examples of a metal in group 5 of the periodic table include, e.g., vanadium (V), niobium (Nb) and tantalum (Ta). Examples of a metal in group 6 of the periodic table include, e.g., chromium (Cr), molybdenum (Mo) and tungsten (W). Examples of a metal in group 7 of the periodic table include, e.g., manganese (Mn), technetium (Tc) and rhenium (Re). Examples of a metal in group 8 of the periodic table include, e.g., iron (Fe), ruthenium (Ru) and osmium (Os). Examples of a metal in group 9 of the periodic table include, e.g., cobalt (Co), rhodium (Rh) and iridium (Ir). Examples of a metal in group 10 of the periodic table include, e.g., nickel (Ni), palladium (Pd) and platinum (Pt). In the present disclosure, the electrode layer preferably contains at least one metal selected from groups 4, 6 and 9 of the periodic table, more preferably contains at least one metal selected from groups 6 and 9 of the metal periodic table, and more preferably contains Mo and/or Co. A layer thickness of the electrode layer is not specifically limited, but is preferably 0.1 nm to 10 μm, more preferably 5 nm to 500 nm, and most preferably 10 nm to 200 nm. Also, in the present disclosure, it is preferable that the electrode layer be one including two or more layers having different compositions. The electrode layer having such preferable configuration enables not only providing a semiconductor element having more excellent Schottky characteristics but also more favorably exerting a leak current curbing effect.

If the electrode layer includes two or more layers including a first electrode layer and a second electrode layer, it is preferable that the second electrode layer have an electrical conductivity that is higher than that of the first electrode layer. A component material of the second electrode layer may be an electrically conductive inorganic material or may be an electrically conductive organic material. In the present disclosure, it is preferable that the material of the second electrode be a metal. In the present disclosure, it is preferable that the material of the second electrode be a metal. Preferable examples of the metal include, e.g., at least one metal selected from groups 8 to 13 of the periodic table. Examples of a metal in groups 8 to 10 of the periodic table include, e.g., the metals indicated by example as metals in groups 8 to 10 of the periodic table in the above-described description of the electrode layer. Examples of a metal in group 11 of the periodic table include, e.g., copper (Cu), silver (Ag) and gold (Au). Examples of a metal in group 12 of the periodic table include, e.g., zinc (Zn) and cadmium (Cd). Also, examples of a metal in group 13 of the periodic table include, e.g., aluminum (Al), gallium (Ga) and indium (In). In the present disclosure, the second electrode layer preferably contains at least one metal selected from groups 11 and 13 of the periodic table and more preferably contains at least one metal selected from silver, copper, gold and aluminum. Note that a layer thickness of the second electrode layer is not specifically limited but is preferably 1 nm to 500 μm, more preferably 10 nm to 100 μm, and most preferably 0.5 μm to 10 μm. Note that in the present disclosure, it is preferable that a film thickness of a part, under an outer end portion of the electrode layer, of the insulator film be larger than a film thickness of a part, in a range of 1 μm from the opening portion, of the insulator film because such larger film thickness enables the semiconductor element having a more excellent voltage resistance property.

Also, in the present disclosure, it is preferable that the Schottky electrode include at least a first metal layer, a second metal layer and a third metal layer, the first metal layer, the second metal layer and the third metal layer include respective different metals, the second metal layer be disposed between the first metal layer and the third metal layer and the first metal layer be located on the semiconductor layer side relative to the third metal layer. Note that if the Schottky electrode includes a first metal layer, a second metal layer and a third metal layer, it is preferable that the first metal layer be a metal layer containing a metal in group 6 of the periodic table or a metal layer containing a metal in group 9 of the periodic table, the second metal layer be a metal layer containing a metal in group 4 of the periodic table and the third metal layer be a metal layer containing a metal in group 13 of the periodic table, and it is more preferable that the first metal layer be a Co layer or an Mo layer, the second metal layer be a Ti layer and the third metal layer be an Al layer.

A method of forming the electrode layer is not specifically limited and may be a publicly known method. Specific examples of the method of forming the electrode layer include, e.g., a dry method and a wet method. Example of the dry method include, e.g., sputtering, vacuum vapor deposition and CVD. Examples of the wet method include, e.g., screen printing and die coating.

Also, in an aspect of the present disclosure, it is preferable that the Schottky electrode have a structure in which a film thickness decreases toward the outer side of the semiconductor element. In this case, the Schottky electrode may include a tapered region in each side surface and the Schottky electrode may include two or more layers including a first electrode layer and a second electrode layer, and an outer end portion of the first electrode layer may be located outside of an outer end portion of the second electrode layer. In an aspect of the present disclosure, if the Schottky electrode includes a tapered region, a taper angle of the tapered region is not specifically limited as long as the taper angle does not hinder the present disclosure, but is preferably no more than 80°, more preferably no more than 60°, and most preferably no more than 40°. A lower limit of the taper angle is not also specifically determined, but is preferably 0.2°, and more preferably 1°. Also, in an aspect of the present disclosure, if the outer end portion of the first electrode layer of the Schottky electrode is located outside of the outer end portion of the second electrode layer, it is preferable that a distance between the outer end portion of the first electrode layer and the outer end portion of the second electrode layer be no less than 1 μm because such distance enables more curbing leak current. Also, in an aspect of the present disclosure, a part of the first electrode layer of the Schottky electrode, the part extending outward of the outer end portion of the second electrode layer (hereinafter also referred to an “extension part”), at least partially has a structure in which a film thickness decreases toward the outer side of the semiconductor element is preferable because such configuration enables providing more excellent voltage resistance of the semiconductor element. Also, combination of such preferable electrode configuration and the above-described preferable component materials of the semiconductor layer enables provision of a lower-loss semiconductor element with leak current more favorably curbed.

It is preferable that the semiconductor element include an oxide semiconductor layer and a dielectric film covering at least side surfaces of the oxide semiconductor layer. Such configuration enables curbing occurrence of a problem in semiconductor characteristic of the oxide semiconductor film due to, e.g., moisture absorption and oxygen in air. Note that in an aspect of the present disclosure, furthermore, tapering side surfaces of the semiconductor layer enables not only enhancement of, e.g., close contact with the dielectric film but also more favorable stress relaxation and thus enables further enhancement of reliability, etc.

The dielectric film is formed on the semiconductor layer and normally includes an opening portion, but is not specifically limited in terms of, e.g., relative permittivity and may be a publicly known dielectric film. In an aspect of the present disclosure, a dielectric film formed in such a manner as to extend at least no less than 1 μm from the opening portion and have a relative permittivity of no more than 5 is preferable. The “relative permittivity” is a ratio between a permittivity of a film and a permittivity of vacuum. In the present disclosure, it is preferable that the dielectric film be a film containing Si. Preferable examples of the film containing Si include a silicon oxide-based film. Examples of the silicon oxide-based film include, e.g., an SiO₂ film, a phosphorus-doped SiO₂ (PSG) film, a boron-doped SiO₂ film, a phosphorus-boron-doped SiO₂ film (BPSG film), an SiOC film and an SiOF film. A method of forming the dielectric film is not specifically limited but examples of the method include, e.g., a CVD method, atmospheric CVD method, a plasma CVD method, a mist CVD method and a thermal oxidation method. In the present disclosure, it is preferable that the method of forming the dielectric film be a mist CVD method or an atmospheric CVD method.

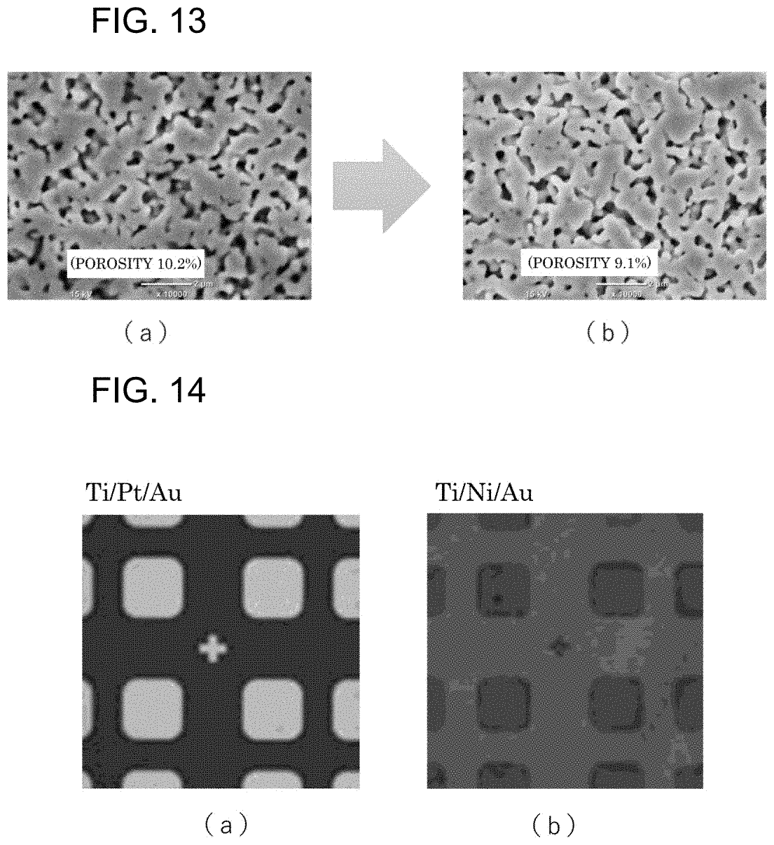

Also, in the semiconductor element in an aspect of the present disclosure, it is preferable that a porous layer be further disposed in contact with the third metal layer of the ohmic electrode. The porous layer is not specifically limited, but preferably has electrical conductivity and more preferably contains a precious metal. In an aspect of the present disclosure, it is preferable that a porosity of the porous layer be no more than 10%. This preferable porosity enables relaxation of, e.g., warpage and concentration of thermal stress without impairing semiconductor characteristics. Note that a method of making the porosity of the porous layer 10% is not specifically limited and may be a publicly known method. It is possible to easily set the porosity of the porous layer to 10% by appropriately setting sintering conditions such as sintering time, pressure and a sintering temperature. Examples of the method include, e.g., a method in which the porosity is adjusted to no more than 10% with compression bonding under heat (thermal compression bonding). More specific examples of the method include, e.g., sintering for sintering time that is longer than normal sintering time, under a fixed pressure. FIG. 13(a) illustrates a porosity where a porous layer formed of Ag was bonded by normal annealing as a test example. As illustrated in FIG. 13(a), the porosity of the porous layer normally exceeds 10%, but as illustrated in FIG. 13(b), compression bonding under pressure of, for example, 0.2 to 10 MPa with heating at, for example, 300° C. to 500° C. for another hour makes the porosity no more than 10%, and use of such porous layer having a porosity of no more than 10% for a semiconductor element enables relaxing, of e.g., warpage and concentration of thermal stress without imparting semiconductor characteristics. Here, the “porosity” refers to a proportion of a volume of space generated by voids in a volume of a porous layer (volume including the voids). It is possible to obtain a porosity of a porous layer based on, for example, a sectional photograph taken using a scanning electron microscope (SEM). More specifically, a sectional photograph (SEM image) of a porous layer is taken from a plurality of positions. Next, the taken SEM images are binarized using commercially available image analysis software to obtain a proportion of parts (for example, black parts) corresponding to holes (voids) in each of the SEM images. The proportions of the black parts obtained from the SEM images taken from the plurality of positions are averaged to determine the resulting proportion as the porosity of the porous layer. Note that the “porous layer” includes not only one in the form of a porous film, which is a continuous film-like structure, but also one in the form of a porous aggregate.

Also, in the semiconductor element of the present disclosure, it is further preferable that a substrate is disposed on the porous layer. Note that the substrate may be directly stacked on the porous layer or the substrate may be stacked on the porous layer with other layers in between such as one or two or more metal layers (for example, metals indicated by example as illustrated above).

In an aspect of the present disclosure, the semiconductor element is not specifically limited in terms of, e.g., a direction in which current flows, it is preferable that a Schottky electrode be disposed on a first surface side of the oxide semiconductor film and an ohmic electrode be disposed on a second surface side opposite from the first surface side, and it is more preferable that the semiconductor element be a vertical device.

### Embodiment

Preferable embodiments of the present disclosure will be described in more detail below with reference to the drawing, but the present disclosure is not limited to these embodiments.

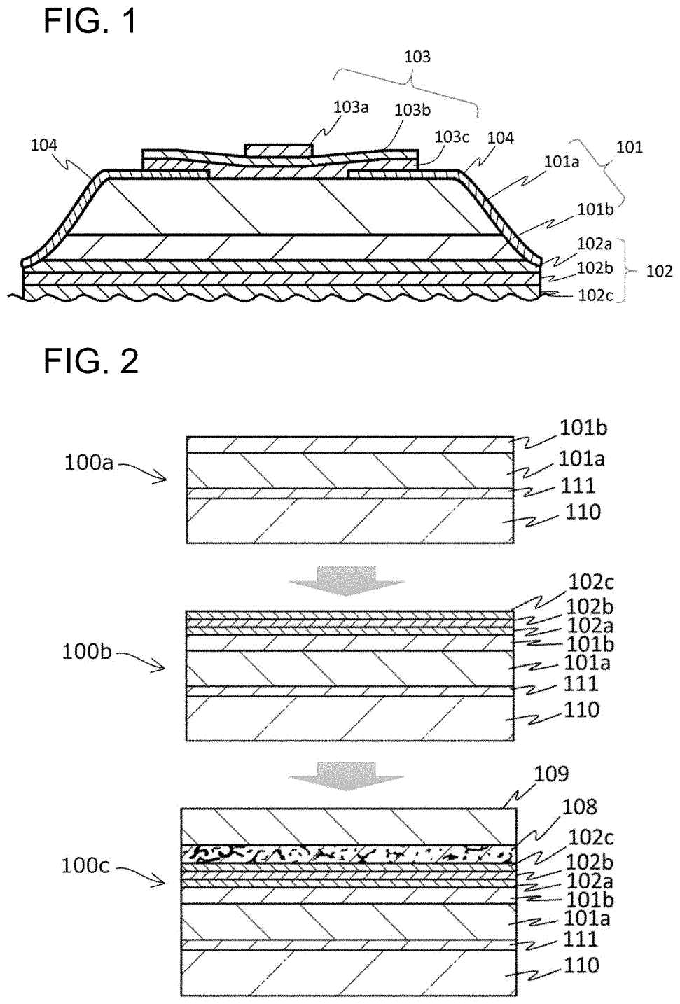

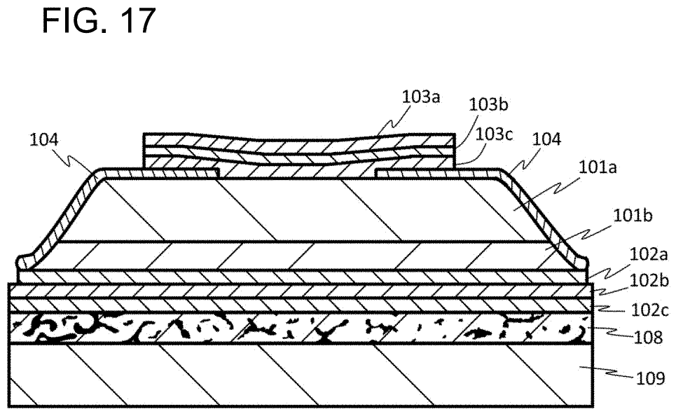

FIG. 1 illustrates a major part of a Schottky barrier diode (SBD) as a semiconductor element that is a preferable embodiment of the present disclosure. The SBD in FIG. 1 includes an ohmic electrode 102, a semiconductor layer 101, a Schottky electrode 103 and a dielectric film 104. The ohmic electrode 102 includes a metal layer 102a, a metal layer 102b and a metal layer 102c. The semiconductor layer 101 includes a first semiconductor layer 101a and a second semiconductor layer 101b. The Schottky electrode 103 includes a metal layer 103a, a metal layer 103b and a metal layer 103c. The first semiconductor layer 101a includes, for example, an n−-type semiconductor layer and the second semiconductor layer 101b is, for example, an n+-type semiconductor layer. Also, the dielectric film 104 (hereinafter may be referred to as an “insulator film”) covers side surfaces of the semiconductor layer 101 (side surfaces of the first semiconductor layer 101a and side surfaces of the second semiconductor layer 101b) and includes an opening portion located on an upper surface of the semiconductor layer 101 (first semiconductor layer 101a). The opening portion is provided between a part of the first semiconductor layer 101a and the metal layer 103c of the Schottky electrode 103. The dielectric film 104 may be provided in such a manner as to cover the side surfaces of the semiconductor layer 101 and cover a part of the upper surface of the semiconductor layer 101 (first semiconductor layer 101a). In the semiconductor element in FIG. 1, the dielectric film 104 enables improvement of a crystal defect at an end portion, more favorable formation of a depletion layer, further enhancement of electric field relaxation and more favorable curbing of leak current. Note that FIG. 17 illustrates a preferable example of an SBD in which a porous layer 108 and a substrate 109 are disposed.

FIG. 6 illustrates a major portion of a Schottky barrier diode (SBD) as a semiconductor element, which is a preferable embodiment of the present disclosure. The SBD in FIG. 6 is different from the SBD in FIG. 1 in including a tapered region in each side surface of the Schottky electrode 103. In the semiconductor element in FIG. 6, outer end portions of a metal layer 103b and/or a metal layer 103c, which correspond to a first metal layer, are located outside of an outer end portion of a metal layer 103a, which corresponds to a second metal layer, enabling more favorably curbing leak current. Furthermore, parts of the metal layer 103b and/or the metal layer 103c, the parts extending outside of the outer end portion of the metal layer 103a, each include a tapered region having a film thickness decreasing toward the outer side of the semiconductor element, providing a configuration having more excellent voltage resistance.

Examples of a material of the metal layer 103a include, e.g., the metals illustrated above by example. Also, examples of component materials of the metal layer 103b and the metal layer 103c include, e.g., the metals illustrated above by example. A method of forming each of the layers in FIG. 1 is not specifically limited as long as such method does not hinder the present disclosure, and may be a publicly known method. Examples of the method include, e.g., a vacuum vapor deposition method, a CVD method, a sputtering method, a method in which a film is formed by any of various coating techniques and then patterned in a photolithography method and a method in which patterning is directly performed using, e.g., a printing technique.

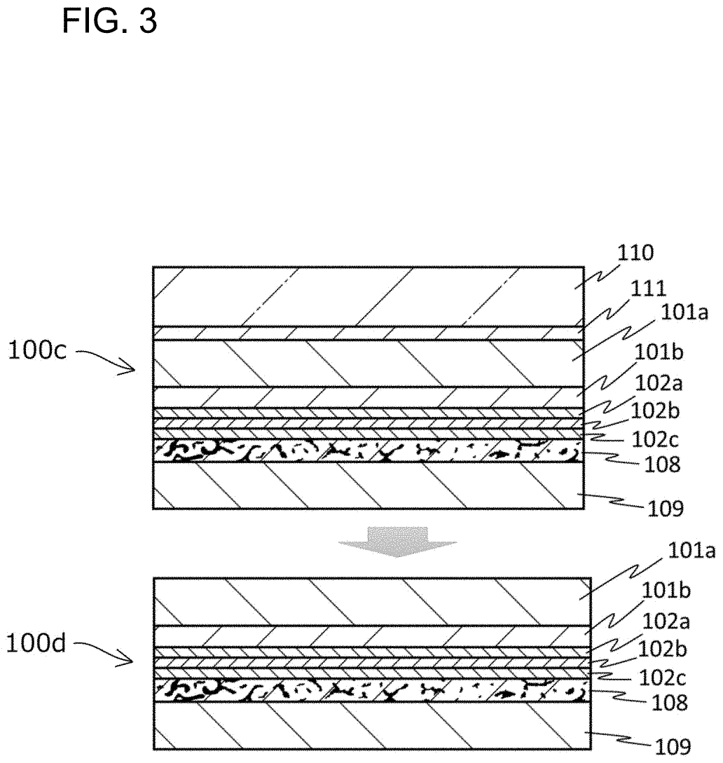

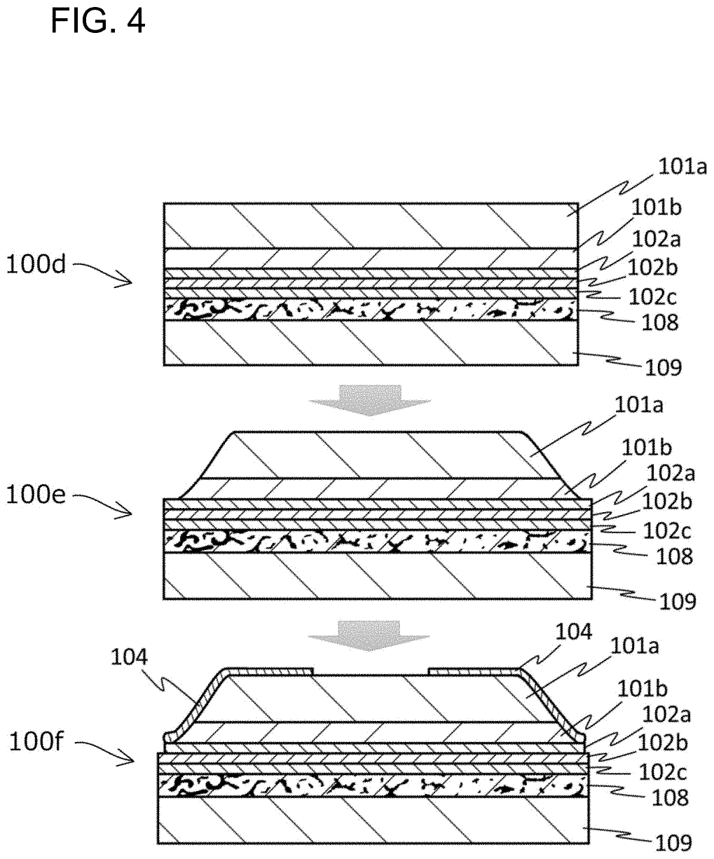

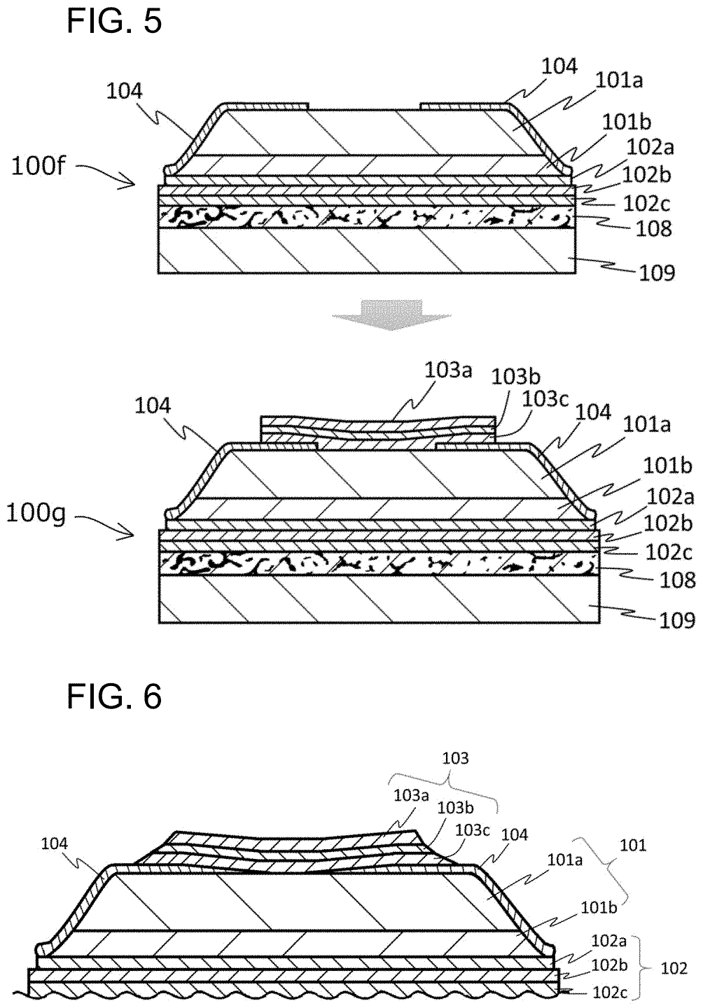

A preferable process of manufacturing the SBD in FIG. 17 will be described below; however, the present disclosure is not limited to these preferable manufacturing methods. FIGS. 2 to 5 are diagram illustrating a mode of a preferable method of manufacturing a semiconductor element according to the present disclosure. FIG. 2 provides illustration from a start with a stack 100a to obtainment of a stack 100c. FIG. 3 provides illustration from the stack 100c to obtainment of a stack 100d. FIG. 4 provides illustration from the stack 100d to obtainment of a stack 100f. FIG. 5 provides illustration from the stack 100f to obtainment of a stack 100g. The stack 100a illustrated in FIG. 2 is formed by stacking a first semiconductor layer 101a and a second semiconductor layer 101b above a crystal growth substrate (sapphire substrate) 110 with a stress relaxation layer 111 in between using the mist CVD method. A stack 100b is obtained by forming a metal layer 102a, a metal layer 102b and a metal layer 102c as an ohmic electrode above the second semiconductor layer 101b of the stack 100a using the dry method or the wet method. The first semiconductor layer 101a is, for example, an n−-type semiconductor layer and the second semiconductor layer 101b is, for example, an n+-type semiconductor layer 101b. Also, the stack 100c illustrated in FIG. 2 is obtained by stacking a substrate 109 on the stack 100b with a porous layer 108 formed of a precious metal in between. Then, as illustrated in FIG. 3, the crystal growth substrate 110 and the stress relaxation layer 111 of the stack 100c are removed using a known removal method to obtain the stack 100d. Then, as illustrated in FIG. 4, side surfaces of the semiconductor layers of the stack 100d are tapered by etching to obtain a stack 100e, and then, a dielectric film 104 is stacked on the tapered side surfaces and an upper surface, except a part corresponding to an opening portion, of the semiconductor layer to obtain the stack 100f. Next, as illustrated in FIG. 5, metal layers 103a, 103b and 103c are formed as a Schottky electrode on a part of the upper surface of the semiconductor layer of the stack 100f, the part corresponding to the opening portion, using the dry method or the wet method to obtain the stack 100g. The semiconductor element obtained as described above has a configuration that enables favorable curbing of diffusion of, e.g., oxygen in the semiconductor layer, provision of excellent ohmic characteristics and improvement of a crystal defect at an end portion, more favorable forming of a depletion layer, further enhancement of electric field relaxation and more favorable curbing of leak current.

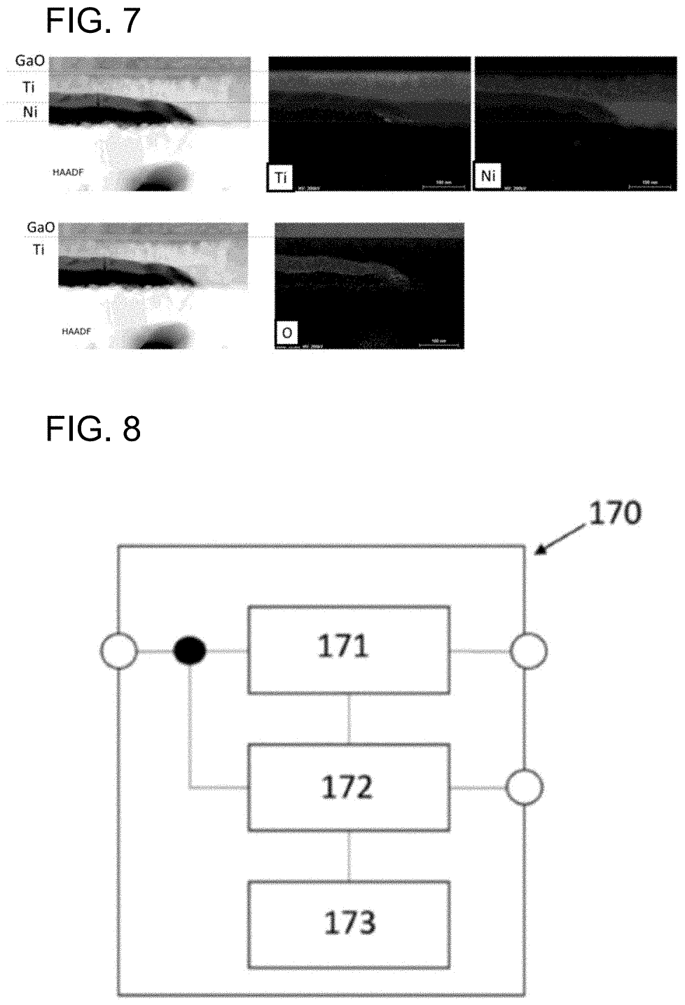

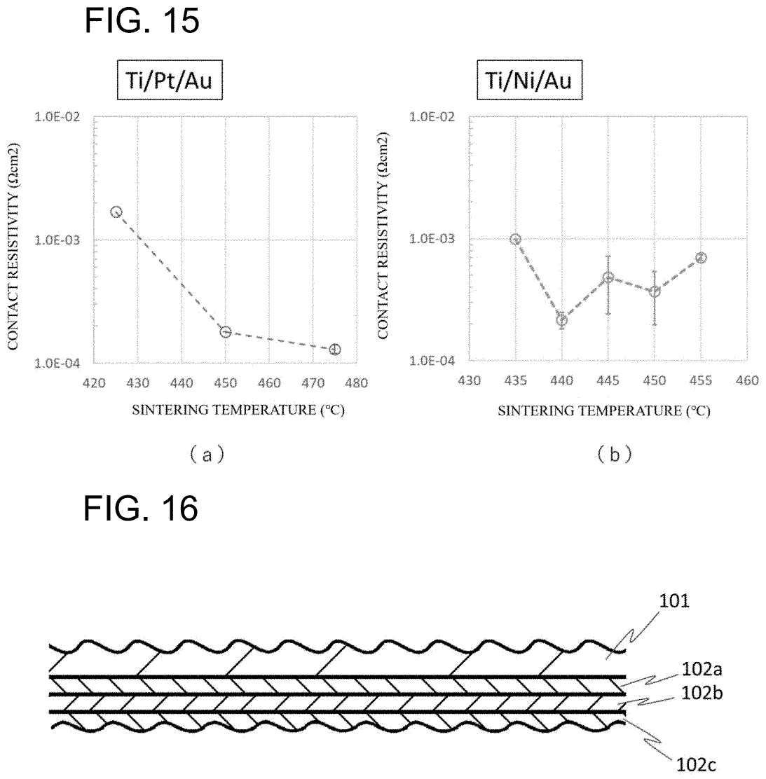

Note that although in the present embodiment, Pt or Pd is used as the metal layer 102b, where Ni is used as the metal layer 102b, for example, as illustrated in FIG. 14, a problem of discoloration occurs. FIG. 14(a) is a photograph showing an outer appearance after sintering where a Ti layer/Pt layer/Au layer (Ti/Pt/Au) was used as an ohmic electrode and FIG. 14(b) is a photograph showing an outer appearance after sintering where a Ti layer/Ni layer/Au layer (Ti/Ni/Au) was used as an ohmic electrode. As is clear from FIG. 14, where Ti/Ni/Au is used as an ohmic electrode in FIG. 14(b), there is a problem of discoloration. Also, FIG. 7 illustrates a result of SEM-EDS where Ti/Ni/Au was used as an ohmic electrode in FIG. 14(b). As illustrated in FIG. 7, it is understandable that where Ti/Ni/Au is used as an ohmic electrode, diffusion of oxygen occurs. Note that FIG. 7 is a diagram illustrating a result of SEM-EDS where Ti/Ni/Au was used as an ohmic electrode, and indicates respective distributions of Ti, Ni and O. As illustrated in the upper portion of FIG. 7, it is understandable that diffusion of Ti was curbed by the Ni layer, and as illustrated in the lower portion of FIG. 7, it is understandable that diffusion of oxygen occurred. Also, respective temperature (sintering temperature) dependances of contact resistivity of a case where Ti/Pt/Au was used as an ohmic electrode and contact resistivity of a case where Ti/Ni/Au was used as an ohmic electrode were evaluated. FIG. 15 illustrates results. In the case where Ti/Pt/Au was used as an ohmic electrode in FIG. 15(a), as the sintering temperature increased, the contact resistivity was favorably lowered. On the other hand, in the case where Ti/Ni/Au was used as an ohmic electrode in FIG. 15(b), a problem such as the contact resistivity increasing as the sintering temperature increases, occurred. Note that when a power cycle test of a product of the present embodiment was conducted for performance evaluation, after completion of 3000 cycles in five minutes, a favorable evaluation result was obtained.

Also, it is preferable that the semiconductor element be a vertical device, and among others, the semiconductor element is useful for a power device. Examples of the semiconductor element include, e.g., diodes (for example, a P-N diode, a Schottky barrier diode and a junction barrier Schottky diode) and transistors (for example, a MOSFET and a MESFET), and among others, diodes are preferable and a Schottky barrier diode (SBD) is more preferable.

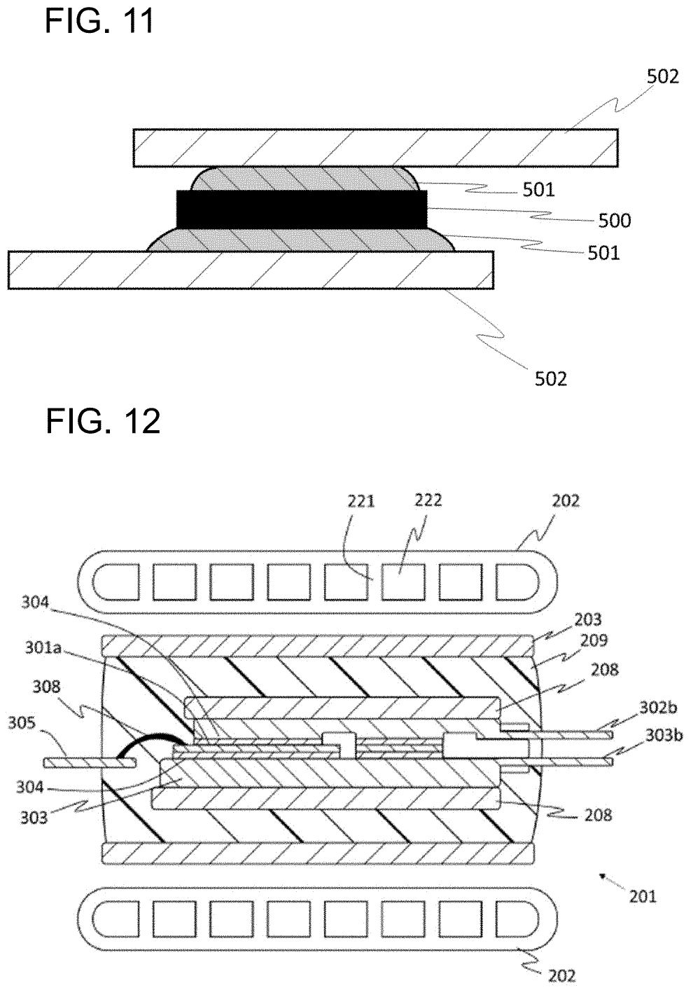

In addition to the above-described matters, the semiconductor element of the present disclosure is suitable for use as a semiconductor device by being bonded to a lead frame, a circuit substrate or a heat dissipation substrate with a bonding member based on a conventional method, and in particular, the semiconductor element is suitable for use as a power module, an inverter or a converter, and furthermore, is suitable for use in, e.g., a semiconductor system using a power supply device. FIG. 11 illustrates a preferable example of the semiconductor device. In the semiconductor device in FIG. 11, each of opposite surfaces of a semiconductor element 500 is bonded to a lead frame, circuit substrate or heat dissipation substrate 502 with a solder 501. Such configuration enables provision of a semiconductor device having excellent heat dissipation performance. Note that in the present disclosure, it is preferable that the peripheries of the bonding members such as solders be encapsulated by resin.

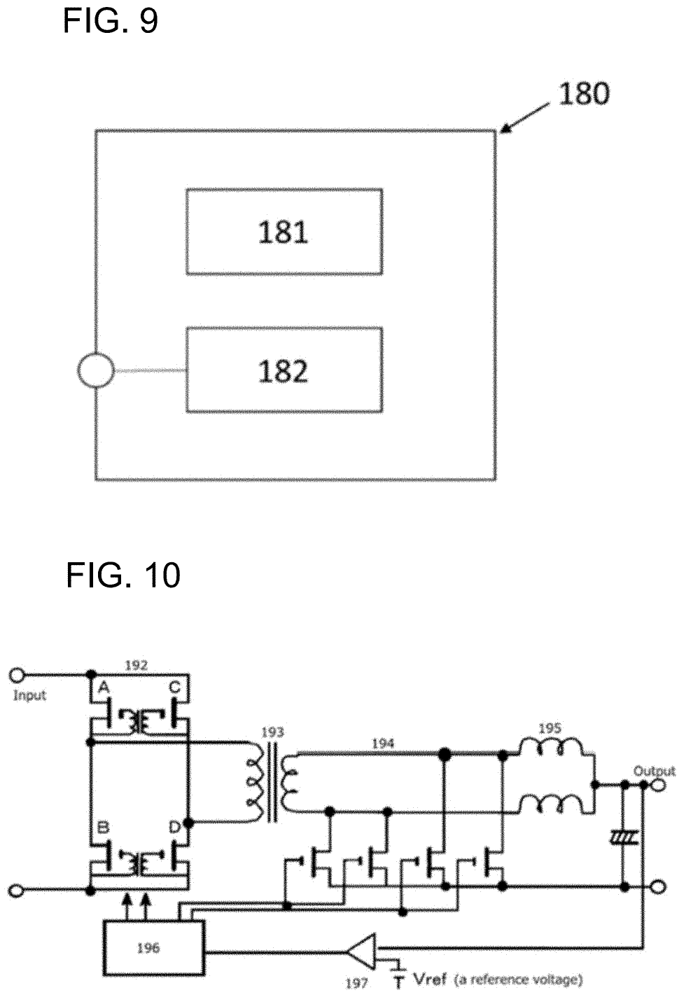

Also, it is possible to fabricate the power supply device from the semiconductor device or as the semiconductor device by connecting the semiconductor device to, e.g., a wiring pattern using a publicly known method. In FIG. 8, a power supply system 170 is configured using a plurality of the power supply devices 171, 172 and a control circuit 173. As illustrated in FIG. 9, the power supply system is usable for a system device 180 in combination of an electronic circuit 181 and a power supply system 182. Note that FIG. 10 illustrates an example of a power supply circuit diagram of a power supply device. FIG. 10 illustrates a power supply circuit of a power supply device formed of a power circuit and a control circuit, and a DC voltage is converted into an AC voltage by being switched at a high frequency by an inverter 192 (formed of MOSFETs A to D) and then, the AC voltage is subjected to insulation and transformation with a transformer 193 and rectified by rectifying MOSFETs 194 (A to B′), and then smoothed by a DCL 195 (smoothing coils L1, L2) and a capacitor to output a direct-current voltage. At this time, the output voltage is compared with a reference voltage in a voltage comparator 197 and a PWM control circuit 196 controls the inverter 192 and the rectifying MOSFETs 194 so that the output voltage becomes a desired output voltage.

In an aspect of the present disclosure, the semiconductor device is preferably a power card, more preferably includes coolers and insulating members, the coolers being provided on opposite sides of the semiconductor layer with at least the insulating members in between, respectively, and most preferably includes heat dissipation layers provided on the opposite sides of the semiconductor layer, respectively, the coolers being provided on respective outer sides of the heat dissipation layers with the insulating members in between, respectively. FIG. 12 illustrates a power card, which is a preferable embodiment of the present disclosure. The power card in FIG. 12 is a double-sided cooling-type power card 201 and includes refrigerant tubes 202, spacers 203, insulating plates (insulating spacers) 208, a resin encapsulating portion 209, a semiconductor chip 301a including a semiconductor element, a metal heat transfer plate (projecting terminal portion) 302b, a heatsink and electrode 303, a metal heat transfer plate (projecting terminal portion) 303b, solder layers 304, a control electrode terminal 305 and a bonding wire 308. A section in a thickness direction of the refrigerant tube 202 includes a multitude of flow channels 222 defined by a multitude of partitioning walls 221 extending in a flow channel direction in such a manner as to be spaced a predetermined distance from one another. Such preferable power card enables provision of higher heat dissipation performance and enables provision of higher reliability.

The semiconductor chip 301a is bonded to a principal surface on the inner side of the metal heat transfer plate 302b with a solder layer 304 and the metal heat transfer plate (projecting terminal portion) 302b is bonded to a remaining principal surface of the semiconductor chip 301a with a solder layer 304. Consequently, an anode electrode surface and a cathode electrode surface of a flywheel diode are connected in what is called inverse-parallel to a collector electrode surface and an emitter electrode surface of an IGBT. Examples of materials of the metal heat transfer plates (projecting terminal portions) 302b and 303b include, e.g., Mo and W. The metal heat transfer plates (projecting terminal portions) 302b and 303b each have thickness variations that absorb thickness variations of the semiconductor chip 301a, and consequently, each of respective outer surfaces of the metal heat transfer plates 302b and 303b is a flat surface.

The resin encapsulating portion 209 is formed of, for example, an epoxy resin and molded in such a manner as to cover side surfaces of the metal heat transfer plates 302b and 303b, and the semiconductor chip 301a is molded by the resin encapsulating portion 209. However, outer principal surfaces, that is, contact/heat receiving surfaces, of the metal heat transfer plate 302b and 303b are completely exposed. The metal heat transfer plates (projecting terminal portions) 302b and 303b project rightward from the resin encapsulating portion 209 in FIG. 9, and the control electrode terminal 305, which is what is called a lead frame terminal, connects, for example, a gate (control) electrode surface of the semiconductor chip 301a with the IGBT formed therein and the control electrode terminal 305.

The insulating plate 208, which is an insulating spacer, is formed of, for example, an aluminum nitride film but may be formed of another insulating film. The insulating plates 208 are in close contact with the metal heat transfer plates 302b and 303b in such a manner as to completely cover the metal heat transfer plates 302b and 303b, respectively; however, the insulating plates 208 and the metal heat transfer plates 302b and 303b may simply be in contact with each other, may be coated with a high thermally conductive material such as silicon grease or may be bonded by any of various methods, respectively. Also, insulating layers may be formed by ceramic spraying, for example, or the insulating plates 208 may be bonded to the metal heat transfer plates or may be bonded to or formed on refrigerant tubes, respectively.

The refrigerant tubes 202 are each fabricated by cutting a plate material into necessary lengths, the plate material being formed by molding an aluminum alloy by a pultrusion molding method or an extrusion molding method. A section in a thickness direction of each refrigerant tube 202 includes a multitude of flow channels 222 defined by a multitude of partitioning walls 221 extending in a flow channel direction in such a manner as to be spaced a predetermined distance from one another. Each of the spacers 203 may be, for example, a flexible metal plate of, e.g., a solder alloy or may be a film formed by, e.g., coating of contact surfaces of the metal heat transfer plates 302b and 303b. A surface of each flexible spacer 203 easily deforms, and fits in minute bumps and dips and warpage of the corresponding insulating plate 208 and minute bumps and dips and warpage of the corresponding refrigerant tube 202, resulting in decrease in thermal resistance. Note that, e.g., known high thermally conductive grease may be applied to, e.g., the surfaces of the spacers 203 or the spacers 203 may be omitted.

The semiconductor element of the present disclosure is usable in various fields of semiconductors (for example, compound semiconductor electronic devices, etc.), electronic components and electrical equipment components, optical and electronic photography-related devices, industrial members, etc., and particularly, is useful for a power device.

The embodiments of the present invention are exemplified in all respects, and the scope of the present invention includes all modifications within the meaning and scope equivalent to the scope of claims.

### REFERENCE SIGNS LIST

101 Semiconductor layer
101a First semiconductor layer
101b Second semiconductor layer
102 Ohmic electrode
102a Metal layer
102b Metal layer
102c Metal layer
103 Schottky electrode
103a Metal layer
103b Metal layer
103c Metal layer
104 Dielectric film
108 Porous layer
109 Substrate
110 Crystal growth substrate
170 Power supply system
171 Power supply device
172 Power supply device
173 Control circuit
180 System device
181 Electronic circuit
182 Power supply system
192 Inverter
193 Transformer
194 Rectifying MOSFET
195 DCL
196 PWM control circuit
197 Voltage comparator
201 Double-sided cooling-type power card
202 Refrigerant tube
203 Spacer
208 Insulating plate (insulating spacer)
209 Resin encapsulating portion
221 Partitioning wall
222 Flow channel
301a Semiconductor chip
302b Metal heat transfer plate (projecting terminal portion)
303 Heatsink and electrode
303b Metal heat transfer plate (projecting terminal portion)
304 Solder layer
305 Control electrode terminal
308 Bonding wire
500 Semiconductor element
501 Solder
502 Lead frame, circuit substrate or heat dissipation substrate

1. A semiconductor element comprising; comprising:
at least a multilayer structure including a semiconductor layer, a first metal layer, a second metal layer and a third metal layer,
the semiconductor layer including an oxide semiconductor film,
the first metal layer, the second metal layer and the third metal layer being arranged on the semiconductor layer,
the first metal layer, the second metal layer and the third metal layer respectively including one or two or more different metals,
the first metal layer being in ohmic contact with the semiconductor layer,
the second metal layer being disposed between the first metal layer and the third metal layer, and
the second metal layer containing Pt or/and Pd.

2. The semiconductor element according to claim 1, wherein the oxide semiconductor film has a corundum structure.

3. The semiconductor element according to claim 2, wherein a principal plane of the oxide semiconductor film is an m-plane.

4. The semiconductor element according to claim 1, wherein the oxide semiconductor film contains gallium oxide and/or iridium oxide.

5. The semiconductor element according to claim 1, wherein the oxide semiconductor film contains gallium oxide.

6. The semiconductor element according to claim 1, wherein the oxide semiconductor film contains a dopant.

7. The semiconductor element according to claim 1, wherein the first metal layer is a Ti layer or an In layer.

8. The semiconductor element according to claim 1, wherein the third metal layer is a metal layer including at least one or two or more metals selected from Au, Ag and Cu.

9. The semiconductor element according to claim 1, further comprising a Schottky electrode.

10. The semiconductor element according to claim 9, wherein the Schottky electrode contains Mo and/or Co.

11. The semiconductor element according to claim 9, wherein the Schottky electrode is disposed on a first surface side of the oxide semiconductor film and an ohmic electrode is disposed on a second surface side of the oxide semiconductor film, and wherein the second surface side is opposite from the first surface side.

12. The semiconductor element according to claim 9, wherein the Schottky electrode includes at least a first metal layer, a second metal layer and a third metal layer, the first metal layer of the Schottky electrode, the second metal layer of the Schottky electrode and the third metal layer of the Schottky electrode respectively include different metals, the second metal layer of the Schottky electrode is disposed between the first metal layer of the Schottky electrode and the third metal layer of the Schottky electrode, and the first metal layer of the Schottky electrode is disposed on the semiconductor layer side relative to the third metal layer of the Schottky electrode.

13. The semiconductor element according to claim 12, wherein the first metal layer of the Schottky electrode is a Co layer or an Mo layer.

14. The semiconductor element according to claim 12, wherein the second metal layer of the Schottky electrode is a Ti layer.

15. The semiconductor element according to claim 12, wherein the third metal layer of the Schottky electrode is an Al layer.

16. The semiconductor element according to claim 1, wherein the semiconductor layer is an n-type oxide semiconductor layer.

17. The semiconductor element according to claim 1, wherein the semiconductor element is a vertical device.

18. The semiconductor element according to claim 1, wherein the semiconductor element is a power device.

19. A semiconductor device comprising at least a semiconductor element bonded to a lead frame, a circuit substrate or a heat dissipation substrate with a bonding member, wherein the semiconductor element is the semiconductor element according to claim 1.

20. The semiconductor device according to claim 19, wherein the semiconductor device is a power module, an inverter or a converter.

21. A semiconductor system comprising a semiconductor element or a semiconductor device, wherein the semiconductor element is the semiconductor element according to claim 1 and the semiconductor device is a semiconductor device comprising at least a semiconductor element bonded to a lead frame, a circuit substrate or a heat dissipation substrate with a bonding member, wherein the semiconductor element of the semiconductor device comprises:
at least a multilayer structure including a semiconductor layer, a first metal layer, a second metal layer and a third metal layer,
the semiconductor layer including an oxide semiconductor film,
the first metal layer, the second metal layer and the third metal layer being arranged on the semiconductor layer,
the first metal layer, the second metal layer and the third metal layer respectively including one or two or more different metals,
the first metal layer being in ohmic contact with the semiconductor layer,
the second metal layer being disposed between the first metal layer and the third metal layer, and
the second metal layer containing Pt or/and Pd.
